(19) United States
(12) Patent Application Publication
(10) Pub. No.: US 2016/0181449 A1
(43) Pub. Date: Jun. 23, 2016

(54) Plasmonic Photovoltaic Devices

(71) Applicant: Brookhaven Science Associates, LLC, Upton, NY (US)

(72) Inventors: Charles T. Black, New York, NY (US); Matthew Sfeir, Bethpage, NY (US)

(73) Assignee: BROOKHAVEN SCIENCE ASSOCIATES, LLC, Upton, NY (US)

(21) Appl. No.: 14/945,666

(22) Filed: Nov. 19, 2015

Related U.S. Application Data
(60) Provisional application No. 62/081,752, filed on Nov. 19, 2014.

(51) Int. Cl. H01L 31/0236; H01L 31/18

(52) U.S. Cl. CPC H01L 31/02363; H01L 31/1884

(57) ABSTRACT

This disclosure provides embodiments of photovoltaic devices. The devices include a light-absorbing anode comprised of an electrically conductive material having a plasmonic structure, a diffusion barrier, and a cathode. The light-absorbing anode and the cathode are separated by the diffusion barrier.

### CROSS REFERENCE TO RELATED APPLICATIONS

This application claims the benefit of U.S. Provisional Application No. 62/081,752 filed on Nov. 19, 2014, the content of which is incorporated by reference herein in its entirety.

This invention was made with Government support under contract numbers DE-AC02-98CH10886 and DE-SC0012704 awarded by the U.S. Department of Energy. The Government has certain rights in the invention.

### FIELD OF THE INVENTION

This disclosure relates generally to photovoltaic energy conversion. In particular, it relates to photovoltaic devices and methods of making the devices.

### BACKGROUND

Photovoltaic energy conversion is a method of generating electrical power by converting sunlight into direct current electricity. The energy conversion is typically performed using semiconducting materials that exhibit a photovoltaic effect. The photovoltaic effect refers to photons of light exciting electrons into a higher state of energy, allowing them to act as charge carriers for an electric current. Materials often used in photovoltaic energy conversion include monocrystalline silicon, polycrystalline silicon, amorphous silicon, cadmium telluride, and copper indium gallium selenide/sulfide. Typically, commercially available solar cell panels include two thin (about 200 micron) slices of a large crystal of silicon, one doped with phosphorous to make n-type silicon, and the other doped with boron to make p-type silicon. However, silicon is expensive to process from raw material to solar cell semiconductor. Therefore, there is a need for photovoltaic energy conversion devices which do not rely on the use of silicon semiconductors.

### SUMMARY

This disclosure provides embodiments of photovoltaic devices. In certain embodiments, the devices include a light-absorbing anode comprised of an electrically conductive material having a plasmonic structure, a diffusion barrier, and a cathode. The light-absorbing anode and the cathode are separated by the diffusion barrier.

Another embodiment provides a method of fabricating a photovoltaic device. The method includes depositing a cathode on a substrate, depositing a barrier layer on the cathode, and depositing a light-absorbing anode comprised of a plasmonic structure.

### BRIEF DESCRIPTION OF THE DRAWINGS

FIG. 1 is a cross-sectional schematic of a photovoltaic device according to an embodiment;

FIG. 2a is a schematic illustration of the top view of a photovoltaic device showing an array of nanostructures according to an embodiment;

FIG. 2b is a schematic illustration of the top view of a photovoltaic device showing an array of holes according to an embodiment;

FIG. 3 is a diagram showing material energy levels in isolation;

FIG. 4a is a device band diagram at zero bias;

FIG. 4b is a device band diagram under illumination at finite bias;

FIG. 5 shows simulated dark and illuminated I-V curves:

FIG. 6 shows the simulated absorption of 125 nm diameter spherical and cylindrical Cu nanostructures;

FIG. 7 shows the normalized transmittance of a Ag film perforated with holes having 600 nm and 450 nm pitch; and

FIG. 8 is a cross-sectional view of a process flow for forming a photovoltaic device according to an embodiment.

### DETAILED DESCRIPTION

This disclosure provides embodiments of photovoltaic devices. Embodiments of the photovoltaic devices include nanostructured electronic devices for photovoltaic energy conversion. The disclosure also presents methods of fabrication, electrical/optical characterization, and modeling of the devices. The devices may separate photogenerated charges by field emission over an asymmetric potential barrier, in contrast to the p/n junction used for charge separation in conventional solar cell designs. The structure employs a nanostructured metal film for solar light absorption, using tunable plasmonic resonance of the nanostructure to maximize photogeneration of charge carriers. The ultimate power conversion efficiency of the photovoltaic devices can approach 20% or more.

By utilizing metal nanostructures for light absorption, and field emission for charge separation, the devices may perform photovoltaic conversion without need for any semiconductor material. Thus, it is possible to produce photovoltaic devices that include essentially no semiconductor materials. The structures may be suited for fabrication using earth abundant materials, for example using copper as the light-absorbing anode, titanium dioxide as the potential barrier for charge transport, and titanium as the cathode.

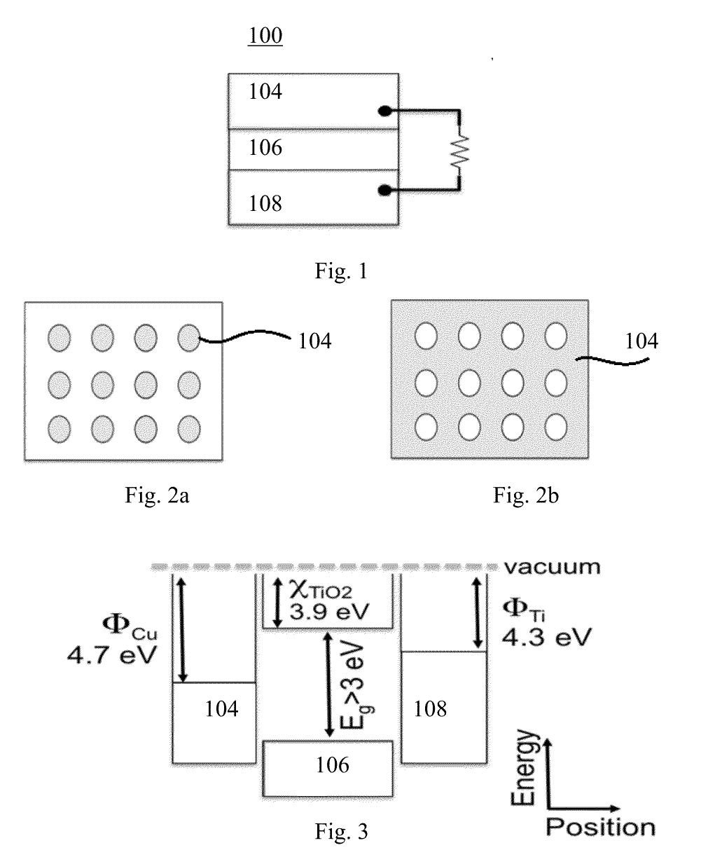

An embodiment of a photovoltaic device 100 is given in FIG. 1. The photovoltaic device 100 includes an anode 104, a barrier 106, and a cathode 108. The cathode 108 may be deposited on a substrate. The substrate may be any suitable material known to be used as a substrate. For example the substrate may be made from fused silica, fused quartz, glass, silicon, silicon dioxide, aluminum oxide, sapphire, germanium, gallium arsenide (GaAs), an alloy of silicon and germanium, indium phosphide (InP), or combinations thereof. In one embodiment, the substrate is glass.

The cathode 108 may be made from any suitable cathode material known. For example, the cathode 108 may include a conducting metal, such as Ti. The cathode 108 may be between about 1 nm and about 1000 nm thick. All individual values and subranges between about 1 to about 1000 nm are included herein and disclosed herein; for example, the thickness may be from a lower limit of about 1, 5, 10, 20, 30, 40, 50, 75, 100, 125, 150, 175, 200, 300, 400, 500 nm to an upper limit of about 250, 275, 350, 375, 400, 425, 450, 475, 500, 600, 700, 800, 850, 900, 950, or 1000 nm. However, it will be appreciated that the present subject matter includes the use of a wide range of thicknesses for this film in the subject structures, such as thicknesses greater than 1000 nm.

Disposed on the cathode 108 is a diffusion barrier 106. The diffusion barrier 106 may provide charge transport from the anode 104 to cathode 108. The diffusion barrier 106 may be made from any suitable diffusion barrier known in the art. For example the diffusion barrier 106 may be made of cobalt, ruthenium, tantalum, tantalum nitride, indium oxide, tungsten nitride, titanium dioxide, and titanium nitride. The diffusion barrier layer may be between about 1 nm and about 1000 nm thick. All individual values and subranges between about 1 to about 1000 nm are included herein and disclosed herein; for example, the thickness may be from a lower limit of about 1, 5, 10, 20, 30, 40, 50, 75, 100, 125, 150, 175, 200, 300, 400, 500 nm to an upper limit of about 250, 275, 350, 375, 400, 425, 450, 475, 500, 600, 700, 800, 850, 900, 950, or 1000 nm. However, it will be appreciated that the present subject matter includes the use of a wide range of thicknesses for this film in the subject structures, such as thicknesses greater than 1000 nm.

The anode 104 may be a light-absorbing anode comprised of an electrically conductive material having a plasmonic structure. The electrically conductive material in the plasmonic structure serves as the plasmonic material and thus can be formed from any suitable material for the intended device or application of the plasmonic structure. Typically, suitable materials for the electrically conductive material include but are not limited to gold, silver, aluminum, copper, indium tin oxide (ITO), other conductive metals and alloys, electrically conductive polymers, and combinations thereof. In one embodiment, the electrically conductive material is copper. The thickness of the anode 104 may be between about 50 nm and about 500 nm thick. All individual values and subranges between about 50 to about 500 nm are included herein and disclosed herein; for example, the thickness may be from a lower limit of about 50, 75, 100, 125, 150, 175, or 200 nm to an upper limit of about 250, 275, 350, 375, 400, 425, 450, 475, or 500 nm. However, it will be appreciated that the present subject matter includes the use of a wide range of thicknesses for this film in the subject plasmonic structures, such as thicknesses less than 50 nm and greater than 500 nm.

The anode 104 may include the electrically conductive material having a plurality of nanoslits as described in U.S. Publication no. US 2013/0201544 which is hereby incorporated herein by reference in its entirety.

Embodiments include anode 104 including arrays of nanostructures (FIG. 2a). The nanostructures may have dimensions of between about 100 nm and about 200 nm along at least one of three orthogonal directions. All individual values and subranges between about 100 to about 200 nm are included herein and disclosed herein; for example, the dimensions may be from a lower limit of about 100, 125, 150, or 175 nm to an upper limit of about 150, 175, or 200 nm.

The center to center distance of the nanostructures in the array may be between about 200 nm and about 500 nm. All individual values and subranges between about 200 to about 500 nm are included herein and disclosed herein; for example, the center to center distance may be from a lower limit of about 200, 225, 250, 275, 300, 350, or 400 nm to an upper limit of about 300, 350, 375, 400, 425, 450, 475, or 500 nm.

In certain embodiments, the nanostructures may be in the form of pillars having a diameter of between about of between about 100 nm and about 200 nm. All individual values and subranges between about 100 to about 200 nm are included herein and disclosed herein; for example, the diameter may be from a lower limit of about 100, 125, 150, or 175 nm to an upper limit of about 150, 175, or 200 nm.

The pillars may have a height of between about 50 nm and about 1000 nm. All individual values and subranges between about 50 to about 1000 nm are included herein and disclosed herein; for example, the height may be from a lower limit of about 50, 75, 100, 125, 150, 175, 200, 300, 400 or 500 nm to an upper limit of about 250, 275, 350, 375, 400, 425, 450, 475, 500, 600, 700, 800, 900, or 10000 nm.

Embodiments also encompass anode 104 consisting of continuous metal films perforated with hole arrays (FIG. 2b). The holes may have diameters of between about 50 nm and about 300 nm. All individual values and subranges between about 500 to about 300 nm are included herein and disclosed herein; for example, the diameters may be from a lower limit of about 50, 75, 100, 125, 150, or 175 nm to an upper limit of about 150, 175, 200, 250, or 300 nm. In certain embodiments the diameters may be between about 200 nm and about 200 nm.

The center to center distance of the holes in the array may be between about 200 nm and about 500 nm. All individual values and subranges between about 200 to about 500 nm are included herein and disclosed herein; for example, the center to center distance may be from a lower limit of about 200, 225, 250, 275, 300, 350, or 400 nm to an upper limit of about 300, 350, 375, 400, 425, 450, 475, or 500 nm

The plasmonic metals may be patterned by techniques known in the art. For example, interference lithography, electron-beam lithography, or imprint lithography may be used to form the plasmonic metal patterns.

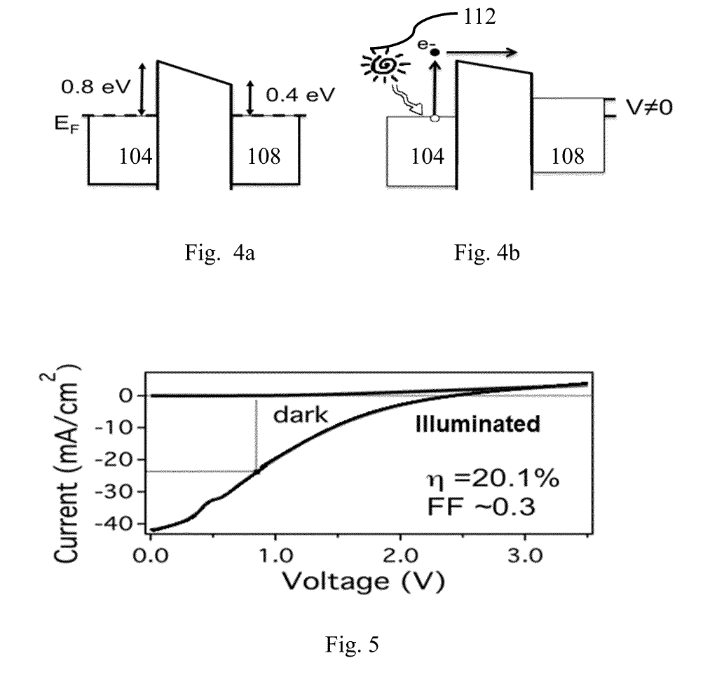

In an embodiment, devices are presented having a copper anode 104, separated from a titanium cathode 108 by a thin titanium dioxide diffusion barrier 106 (χ_{TiO2}=3.9 eV; work functions, Φ, and electron affinity, χ, shown in FIG. 3). At zero bias, the work function difference between Cu anode (Φ_{Cu}=4.7 eV) and Ti cathode (Φ_{Ti}=4.3 eV) generates an internal electric field that creates a trapezoidal potential barrier (FIG. 4a), with maximum barrier height of ˜0.8 eV. Electrons photoexcited by light 112 in the anode with energy >0.8 eV can inject over the potential barrier and transport to the Ti cathode through the TiO₂ (FIG. 4b), producing a current. The reverse process—charge backstreaming from the Ti cathode to Cu anode at finite voltage—is minimized if there is no means for light absorption in the cathode, and by the 0.4 eV barrier for electron injection from Ti to TiO₂.

A simplified device simulation under illumination illustrates features of operation (FIG. 5) and provides insight into understanding and optimizing device efficiency. Here, it is assumed the mean free path of photoexcited electrons is long compared to the metal film thickness, and, for simplicity, the calculation is performed at zero temperature. It is found that the dominant contribution to the photocurrent is field emission of charge carriers photoexcited over the potential barrier at the Cu anode (0.8 eV). A second contribution from tunneling through the barrier (computed within the WKB approximation) is smaller (<10% of the total current), even for ˜1 nm thick insulating layers.

The device open circuit voltage (V_{oc}) is determined by the point at which photoexcited carriers can no longer traverse the potential barrier. For example, the simulations show that for ballistic transport across the barrier, the device continues to generate photocurrent even when the internal electric field opposes the charge transport direction. The device can support V_{oc}>2 volts—significantly higher than that of conventional solar cells (FIG. 5). The cost of this high voltage is a comparatively degraded device fill factor compared to conventional devices (FF˜0.3 in FIG. 5). Even so, this simulation shows that efficiencies approaching η˜20% are possible for a suitably strong absorber.

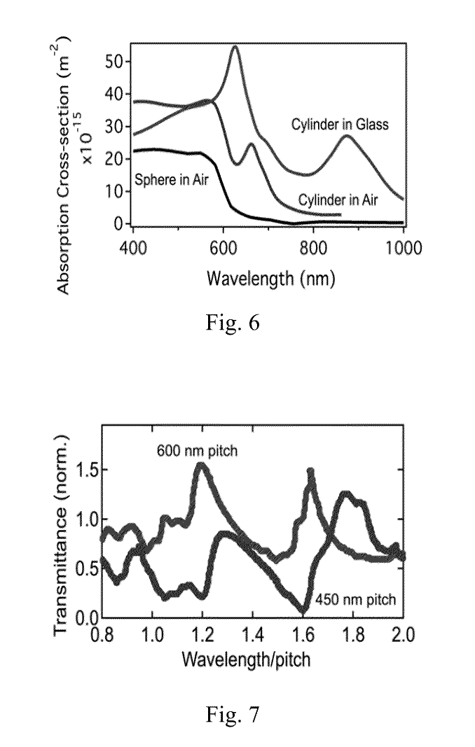

Discrete dipole approximation (DDA) has been used for comparing the shape and dielectric dependence of isolated Cu nanostructures (such as depicted in FIG. 2c). As can be seen in FIG. 6, changing from a spherical to cylindrical shape generates sharp absorption resonances in the visible portion of the spectrum. Furthermore, embedding the cylindrical plasmonic object in a glass dielectric further enhances and red shifts the absorption features.

In an embodiment, the anode 104 is a continuous Cu film perforated with a 2D array of holes (as depicted in FIG. 2b) because of its dual benefit of providing an electrically conducting anode. Recent work has shown that periodic Ag nanostructures fabricated on an appropriate dielectric stack support high absorption over a large spectral range. As a practical demonstration of tuning plasmonic resonances in such nanostructures, FIG. 7 show the far field optical transmission spectra of two Ag films on glass containing hole arrays with 600 nm and 450 nm pitches, fabricated using a focused ion beam, and measured with a high brightness Fourier transform spectroscopy apparatus. The transmission spectrum maxima correspond to propagating plasmonic resonances (in a device, reflections at the metal contact redistribute energy to the metal-dielectric interface). The minima are evanescent modes at the air-metal and metal-dielectric interfaces. Simulations show that plasmonic metals patterned with dimensions between 100-200 nm and separations between ˜200-500 nm can provide a broadband light absorbing layer.

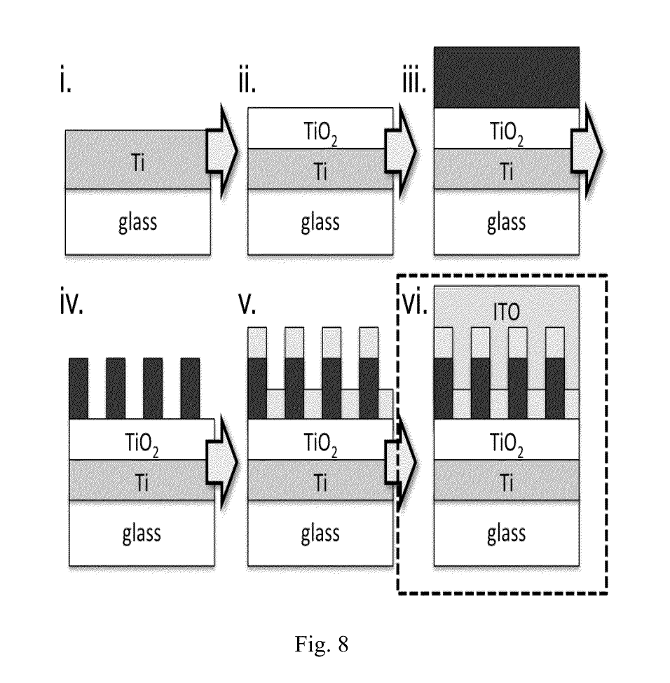

Embodiments encompass processes for the fabrication of embodied photovoltaic devices. FIG. 8 is a cross-sectional view of a process flow beginning with a cathode (such as Ti thin film) deposited on a substrate, such as glass (FIG. 8, part i). A diffusion barrier (such as TiO₂ insulating layer) is grown (ii) such as by thermal oxidation or atomic layer deposition, prior to being coated with photoresist (black layer, part iii) and patterned by, for example, interference lithography (iv). The nanostructured plasmonic layer (such as Cu) is formed by physical vapor deposition onto the patterned photoresist (v). In certain embodiments, the unexposed photoresist remains part of the final device structure. When the Cu layer is formed of nanoparticles, device fabrication is completed by depositing a transparent conducting film (such as for example indium tin oxide, ITO) by sputtering (vi), a step unnecessary for the perforated Cu anode device.

The description has not attempted to exhaustively enumerate all possible variations. The alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent. Furthermore, all references, publications, U.S. Patents, and U.S. Patent Application Publications cited throughout this specification are incorporated by reference as if fully set forth in this specification.

1. A photovoltaic device, comprising:
a light-absorbing anode comprised of an electrically conductive material having a plasmonic structure;
a diffusion barrier; and
a cathode, wherein the light-absorbing anode and the cathode are separated by the diffusion barrier.

2. The photovoltaic device of claim 1, wherein the photovoltaic device comprises essentially no semiconductor materials.

3. The photovoltaic device of claim 1, wherein the plasmonic structure comprises gold, silver, aluminum, copper, indium tin oxide (ITO), electrically conductive polymers, or combinations thereof.

4. The photovoltaic device of claim 1, wherein the plasmonic structure comprises a plasmonic metal film.

5. The photovoltaic device of claim 4, wherein the plasmonic metal film comprises a metal film perforated with an array of a plurality of holes having a diameter between about 100 nm and about 200 nm.

6. The photovoltaic device of claim 5, wherein the plurality of holes have a center to center distance of between about 200 nm and about 500 nm.

7. The photovoltaic device of claim 1, wherein the plasmonic structure has a thickness of between about 50 nm and about 500 nm.

8. The photovoltaic device of claim 1, wherein the plasmonic structure comprises an array of a plurality of nanostructures having dimensions of between about 100 nm and about 200 nm along at least one of three orthogonal directions.

9. The photovoltaic device of claim 8, wherein the plurality of nanostructures have a center to center distance of between about 200 nm and about 500 nm.

10. The photovoltaic device of claim 8, wherein the plasmonic structure plurality of nanostructures comprises pillars having a diameter of between about 100 nm and about 200 nm and a height of between about 100 nm and about 500 nm .

11. The photovoltaic device of claim 1, wherein the diffusion barrier comprises at least one of cobalt, ruthenium, tantalum, tantalum nitride, indium oxide, tungsten nitride, titanium dioxide, and titanium nitride.

12. The photovoltaic device of claim 10, wherein the diffusion barrier comprises a metal oxide.

13. The photovoltaic device of claim 12, wherein the metal oxide comprises TiO₂.

14. The photovoltaic device claim 1, wherein the cathode comprises a conducting metal.

15. The photovoltaic device of claim 14, wherein the cathode comprises Ti.

16. The photovoltaic device of claim 8, further comprising patterned photoresist on the barrier.

17. A method of fabricating a photovoltaic device:
depositing a cathode on a substrate;
depositing a barrier layer on the cathode; and
depositing a light-absorbing anode comprised of a plasmonic structure.

18. The method of claim 17, further comprising depositing a photoresist layer on the barrier layer and patterning the photoresist layer before depositing the light-absorbing anode.

19. The method of claim 18, further comprising depositing a transparent conducting film on the plasmonic structure.

20. The method of claim 19, wherein the transparent conducting film comprises indium tin oxide.
